(19) United States
(12) Patent Application Publication
(10) Pub. No.: US 2010/0327426 A1
(43) Pub. Date: Dec. 30, 2010

(54) Semiconductor chip package and method of manufacturing the same

(75) Inventors: Seung Wook Park, Suwon (KR); Young Do Kweon, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/591,833

(22) Filed: Dec. 2, 2009

(30) Foreign Application Priority Data
Jun. 29, 2009 (KR) 10-2009-0058359

(51) Int. Cl. H01L 23/48; H01L 21/60

(52) U.S. Cl. 257/692; 438/121; 257/E23.01; 257/E21.506

(57) ABSTRACT

Provided are a semiconductor chip package and a method of manufacturing the same. The semiconductor chip package includes a semiconductor chip including a first face having a chip pad, a second face facing the first face, and a side face connecting the first and second faces, a first lamination layer covering the second face and a portion of the side face, a second lamination layer disposed on a top surface of the first lamination layer and forming a gap having a predetermined distance from the side face, and a redistribution pattern disposed on the first face and electrically connected to the chip pad. The semiconductor package and the method of manufacturing the same achieve a high process yield and reliability.

### CROSS-REFERENCE TO RELATED APPLICATIONS

This application claims the priority of Korean Patent Application No. 10-2009-0058359 filed on Jun. 29, 2009, in the Korean Intellectual Property Office, the disclosure of which is incorporated herein by reference.

### BACKGROUND OF THE INVENTION

1. Field of the Invention

The present invention relates to a semiconductor package and a method of manufacturing the same, and more particularly, to a semiconductor chip package and a method of manufacturing the same, which can achieve high reliability and production yield.

2. Description of the Related Art

In general, one of main trends in semiconductor technology development is the reduction in size of semiconductor devices. Even in the field of semiconductor packages, a semiconductor package, such as a fine pitch ball grid array (FBGA) or a chip scale package (CSP) is currently under development, which can realize a plurality of pins while having a small size.

The semiconductor package such as an FBGA or a CSP, both of which are currently under development, has physical advantages such as a small size and a light weight. However, this type of semiconductor package has limitations in that it has not yet ensured reliability equal to that of a related art plastic package, and has low price competitiveness due to the high unit costs of subsidiary materials and processes consumed in the manufacturing process. Also, a micro BGA (μBGA), a representative kind of chip scale package, is advantageous over the FBGA or CSP, but still has the limitations of low reliability and price competitiveness.

An example of a package developed for the purpose of overcoming the above limitations includes a wafer level CSP (WL-CSP) using the redistribution or rerouting of the bonding pads of semiconductor chips formed on a wafer. The WL-CSP using redistribution is characterized structurally in that, in a semiconductor-device fabrication process (FAB), bonding pads on a semiconductor substrate are redistributed using other pads having a greater size, and external connection terminals such as solder balls are then formed thereon.

### SUMMARY OF THE INVENTION

An aspect of the present invention provides a semiconductor chip package having a high process yield and reliability and a method of manufacturing the same.

According to an aspect of the present invention, there is provided a semiconductor chip package including: a semiconductor chip including a first face having a chip pad, a second face facing the first face, and a side face connecting the first and second faces; a first lamination layer covering the second face and a portion of the side face; a second lamination layer disposed on a top surface of the first lamination layer and forming a gap having a predetermined distance from the side face; and a redistribution pattern disposed on the first face and electrically connected to the chip pad.

The first lamination layer may include an extension portion formed in the gap having the predetermined distance.

The first lamination layer and the second lamination layer may each be formed of polypropylene glycol (PPG) or a liquid crystal polymer (LCP).

The first lamination layer and the second lamination layer may be formed of the same kind of material.

The semiconductor chip package may further include an insulating layer formed on the first face and the second lamination layer and exposing a portion of the chip pad.

The insulating layer may include an extension portion formed in the gap having the predetermined distance formed by the second lamination layer and the side face.

The semiconductor chip package may further include a via contact electrically connected to the redistribution pattern and penetrating the first and second lamination layers.

According to another aspect of the present invention, there is provided a method of manufacturing a semiconductor chip package, the method including: forming a through hole in a second lamination layer to which a support is attached; mounting a semiconductor chip in the through hole such that a first face of the semiconductor chip faces downwards; forming a first lamination layer on the second lamination layer and the second face; exposing the first face by removing the support; and forming a redistribution pattern electrically connected to a chip pad of the first face.

The second lamination layer may have a smaller height than a side face of the semiconductor chip.

The first lamination layer may cover a portion of a side face of the semiconductor chip.

The through hole may have a wider area than the first face of the semiconductor chip so as to form a gap having a predetermined distance between the second lamination layer and a side face of the semiconductor chip.

The first lamination layer may have an extension portion formed in the gap.

The method may further include, after the exposing of the first face, forming an insulating layer on the first face of the semiconductor chip and the second lamination layer, the insulating layer exposing a portion of the chip pad of the first face.

The method may further include, after the forming of the first lamination layer, forming a via hole penetrating the first and second lamination layers to form a via contact electrically connected to the redistribution pattern.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic plan view illustrating a semiconductor chip package according to an exemplary embodiment of the present invention;

FIG. 2 is a schematic cross-sectional view taken along line I-I′ of FIG. 1, illustrating a semiconductor chip package according to an exemplary embodiment of the present invention;

FIG. 3 is a schematic cross-sectional view illustrating a semiconductor chip package according to another exemplary embodiment of the present invention;

FIGS. 4 through 10 are cross-sectional views for illustrating a method of manufacturing a semiconductor chip package according to an exemplary embodiment of the present invention; and

FIGS. 11 through 13 are cross-sectional views for illustrating a method of manufacturing a semiconductor chip package according to another exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements are exaggerated for clarity.

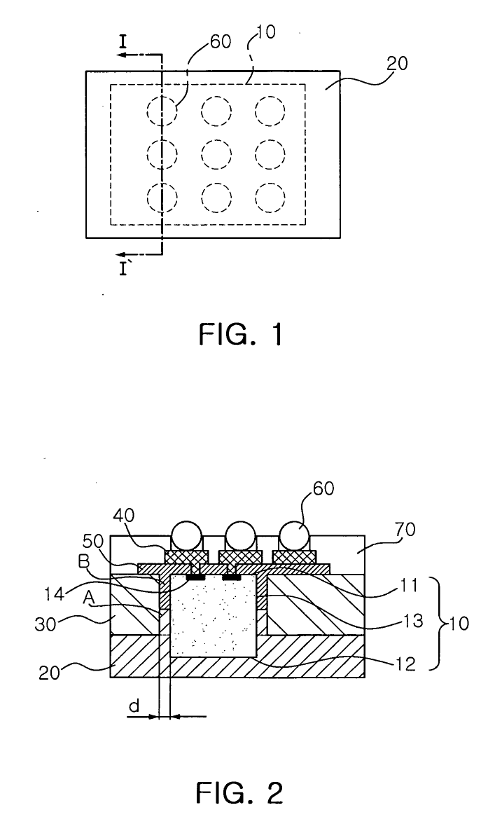

Referring to FIGS. 1 and 2, a semiconductor chip package, according to an exemplary embodiment of the present invention, will now be described. FIG. 1 is a schematic plan view illustrating a semiconductor chip package according to an exemplary embodiment of the present invention, and FIG. 2 is a schematic cross-sectional view taken along line I-I′ of FIG. 1, illustrating the semiconductor chip package.

A semiconductor chip package, according to this embodiment, includes a semiconductor chip 10 including a first face 11 having a chip pad 14 thereon, a second face 12 facing the first face 11, and a side face 13 connecting the first and second faces 11 and 12; a first lamination layer 20 covering the second face 12 and a portion of the side face 13; a second lamination layer 30 disposed on the top surface of the first lamination layer 20 and forming a gap having a predetermined distance d from the side face 13; and a redistribution pattern 40 formed on the first face 11 and electrically connected with the chip pad 14.

The first face 11 and the second face 12 of the semiconductor chip 10 may be parallel to each other, and the side face 13 connecting the first and second faces 11 and 12 together may meet the first and second faces 11 and 12 in a perpendicular manner. The side face 13 may have four faces.

The semiconductor chip 10 may include therein a semiconductor device such as a memory, a logic, a passive device or the like.

The chip pad 14 of the first face 11 may be a unit that electrically connects a semiconductor device with an external substrate.

The semiconductor chip 10 is molded by the first lamination layer 20 and the second lamination layer 30. The first lamination layer 20 covers the second face 12 of the semiconductor chip 10 and a portion of the side face 13. The second lamination layer 20 is disposed on the top surface of the first lamination layer 20, and forms a gap having a predetermined distance d from the side face 13. The first lamination layer 20 may include an extension portion A formed in the gap having the predetermined distance d between the second lamination layer 30 and the side face 13.

According to this embodiment, a lamination process is used for the molding of a semiconductor chip, instead of the related art printing or compression molding. The semiconductor chip is molded by the first and second lamination layers 20 and 30.

The first and second lamination layers 20 and 30 may be formed of a material having a low coefficient of thermal expansion (CTE). Although not limited, the first and second lamination layers 20 and 30 may each be formed of polypropylene glycol (PPG) or a liquid crystal polymer (LCP).

The first and second lamination layers 20 and 30 may be formed of the same material or different kinds of materials.

The second face 12 and the portion of the side face 13 of the semiconductor chip 10 are molded by the first lamination layer 20, and the other portion of the side face 13 is molded by the second lamination layer 3, such that the semiconductor chip 10 can be protected chemically/physically from external environments. Here, the first face 11 having the chip pad 14 is not molded by the first and second lamination layers 20 and 30.

The first face 11 having the chip pad 14 includes a redistribution pattern 40 electrically connected with the chip pad 14. The redistribution pattern 40 may be a unit that connects the semiconductor chip 10 with an external substrate. The redistribution pattern 40 may be formed of Al, Cu, Sn, Ni, Au, Pt and an alloy thereof, or may have a multilayer structure of Cu/Au/Ni laminated in a sequential order.

The semiconductor chip package, according to this embodiment, may include an insulating layer 50 formed on the first face 11 and the second lamination layer 30 and exposing a portion of the chip pad 14.

The insulating layer 50 may include an extension portion B formed in the gap having the predetermined distance d between the second lamination layer 30 and the side face 13 of the semiconductor chip 10. The insulating layer 50 may utilize a dielectric material developed for lamination.

In addition, a protruding connection terminal 60 may be provided on the redistribution pattern 40. The protruding connection terminal 60 may be a unit that electrically connects the semiconductor chip 10 with an external substrate. The protruding connection terminal 60 may be a solder ball or a bump.

Although not shown, an under bump metallization (UBM) layer may be provided between the redistribution pattern 40 and the protruding connection terminal 60.

For the purpose of structural support and electrical isolation, a passivation layer 70 may be formed on the second lamination layer 30, the insulating layer 50 and the redistribution pattern 40.

The passivation layer 70 maybe formed of an insulating material such as silicon dioxide (SiO₂), silicon oxynitride (SiON), silicon nitride (SiₓN_{y}), polyimide (PI), benzocyclo butene (BCB) or polybenzo-oxazole (PBO).

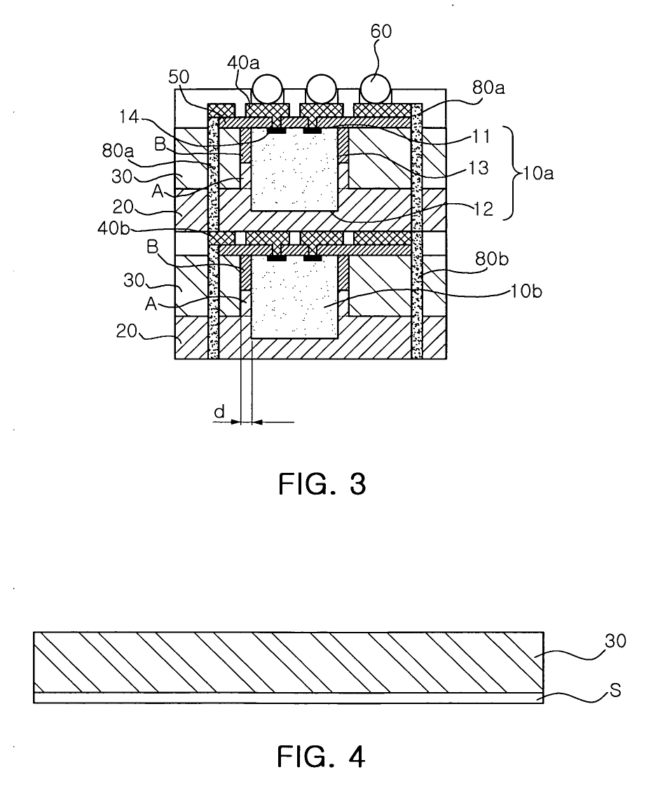

FIG. 3 is a schematic cross-sectional view illustrating a semiconductor chip package according to another exemplary embodiment of the present invention. Different elements from the above-described embodiment will be mainly described, and detailed description of like elements will be omitted.

According to this embodiment, via contacts 80a and 80b are provided. The via contacts 80a and 80b are electrically connected with redistribution patterns 40a and 40b and penetrate the first and second lamination layers 20 and 30, respectively. The via contacts 80a and 80b may be formed of Al, Cu, Zn, Ni, Au or Ag.

The via contacts 80a and 80b, included as in this embodiment, allow for the formation of a multilayer package. As shown in FIG. 3, the multilayer package may include first and second semiconductor chips 10a and 10b, and the first semiconductor chip 10a may be electrically connected to the second semiconductor chip 10b by the via contact 80a electrically connected to the redistribution pattern 40a. That is, the via contact 80a is electrically connected to the via contact 80b electrically connected to the redistribution pattern 40b of the second semiconductor chip 10b.

FIGS. 4 through 10 are cross-sectional views for explaining a method of manufacturing a semiconductor chip package according to an exemplary embodiment of the present invention.

As shown in FIG. 4, a second lamination layer 30 to which a support S is attached is provided. As described above, the second lamination layer 30 is formed of a material having a low CTE, for example, PPG or LCP.

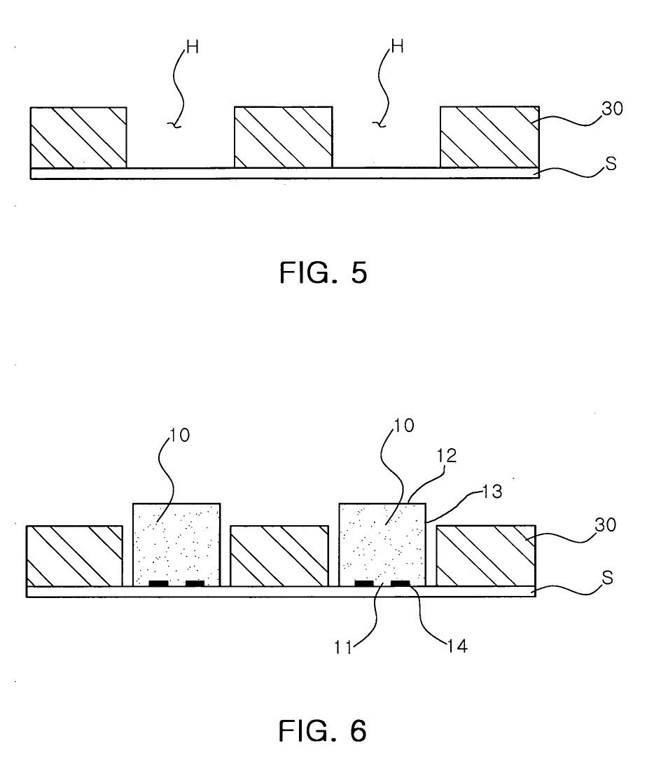

Subsequently, as shown in FIG. 5, through holes H are formed in the second lamination layer 30 for the mounting of semiconductor chips.

As shown in FIG. 6, semiconductor chips 10 are mounted in the through holes H respectively, such that active regions where chip pads are formed face downwards. In this embodiment, the semiconductor chips 10 may each include a first face 11 having a chip pad 14, a second face 12 facing the first face 11, and a side face 13 connecting the first and second faces 11 and 12.

The semiconductor chips 10 may be loaded, attached on a carrier tape (not shown). The carrier tape may utilize a polyimide (PI) tape.

The second lamination layer 30 may have a smaller height than that of the side face 13 of each semiconductor chip 10.

In addition, the through holes H may each have a wider area than the first face 11 of the semiconductor chip 10. In this case, a gap having a predetermined distance d may be formed between the semiconductor chip 10 and the second lamination layer 30.

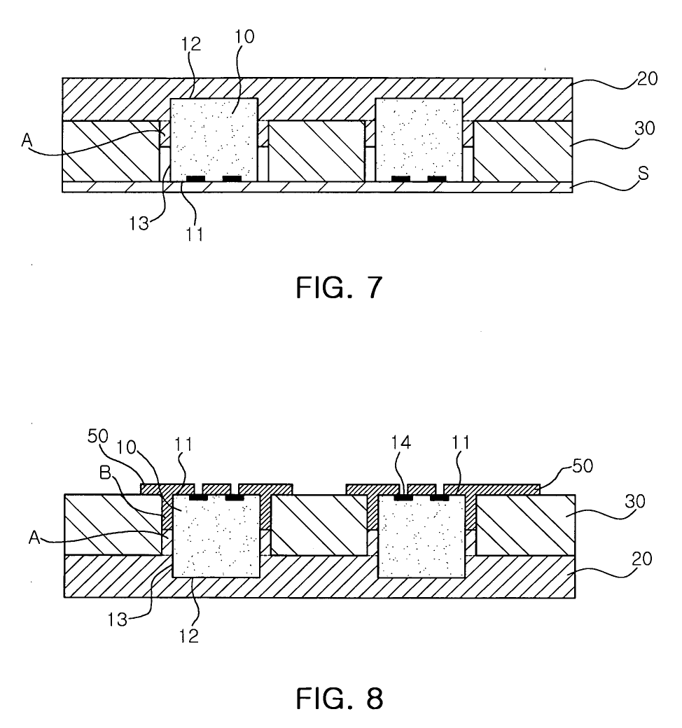

Thereafter, after shown in FIG. 7, a first lamination layer 20 is formed on the second lamination layer 30 and the second face 12.

In the event that the second lamination layer 30 has a lower height than the side face 13 of the semiconductor chip 20, the first lamination layer 20 may cover a portion of the side face 13.

The first lamination layer 20 may have an extension portion A formed into the gap having the predetermined distance d between the second lamination layer 30 and the side face 13. That is, when the through hole H has a wider area than the first face 11 of the semiconductor chip 10, the gap with the predetermined distance d is formed between the semiconductor chip 10 and the second lamination layer 30. In the process of forming the first lamination layer 20, the first lamination layer 20 may be caused to have the extension portion A in the gap having the predetermined distance d by controlling the viscosity and pressure of the material of the first lamination layer 20.

In this embodiment, the semiconductor chips 10 are molded by the first and second lamination layers 20 and 30, and may be then cured using spot-curing. The shift of the semiconductor chips 10 may be minimized due to the extension portion A of the first lamination layer 20.

Subsequently, as shown in FIG. 8, the support S is removed to expose each first face 11 having the chip pad 14.

According to this embodiment, since the first faces 11 of the semiconductor chips 10, each having the chip pad, are mounted on the second lamination layer 30 to which the support S is attached, the semiconductor chips 10 may have their active surfaces placed at the same level. This facilitates subsequent wafer-level packaging processes such as the process of forming redistribution patterns.

Thereafter, redistribution patterns are formed and are each electrically connected to the chip pad of the first face 11.

As shown in FIG. 8, an insulating layer 50 is formed on the respective first faces 11 of the semiconductor chips 10 and the second lamination layer 30. The insulating layer 50 is then patterned to expose portions of the chip pads of the first faces 14.

Here, the insulating layer 50 may have an extension portion B formed in the gap having the predetermined distance d between the second lamination layer 50 and the side face 13 of each semiconductor chip 10.

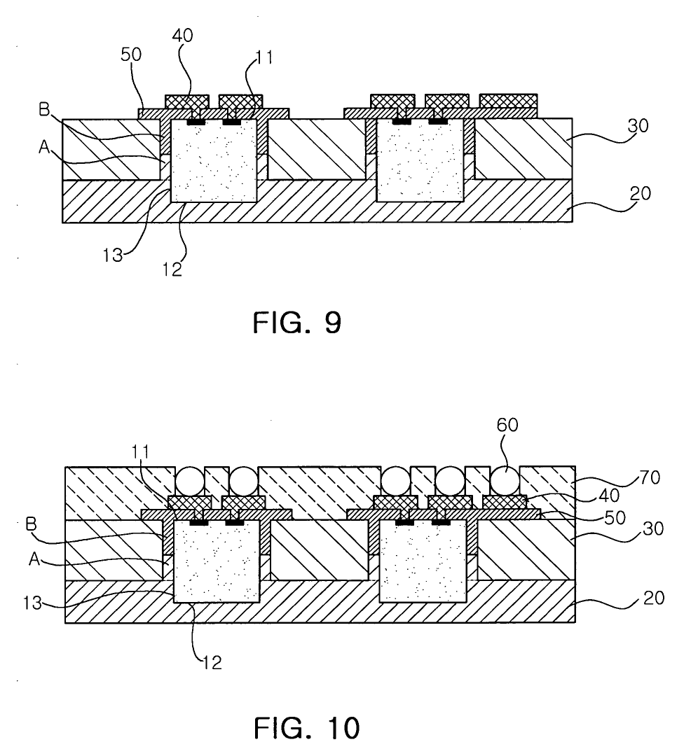

Thereafter, as shown in FIG. 9, redistribution patterns 40 are formed and electrically connected to the chip pads opened by the insulating layer 50. The formation of the redistribution patterns 40 is performed by the processes of forming a conductive layer, applying a photoresist layer, and light-exposing and developing a resultant structure.

Subsequently, a passivation layer 70 may be formed on the second lamination layer 30, the insulating layer 50, and the redistribution patterns 40.

Protruding connection terminals 60 may be formed on the redistribution patterns 40, respectively. The passivation layer 70 may expose a region in which the protruding connection terminals 60 are to be formed, by using a photoresist pattern.

Although not shown, an UBM layer may be formed between the redistribution pattern 40 and the protruding connection terminal 60.

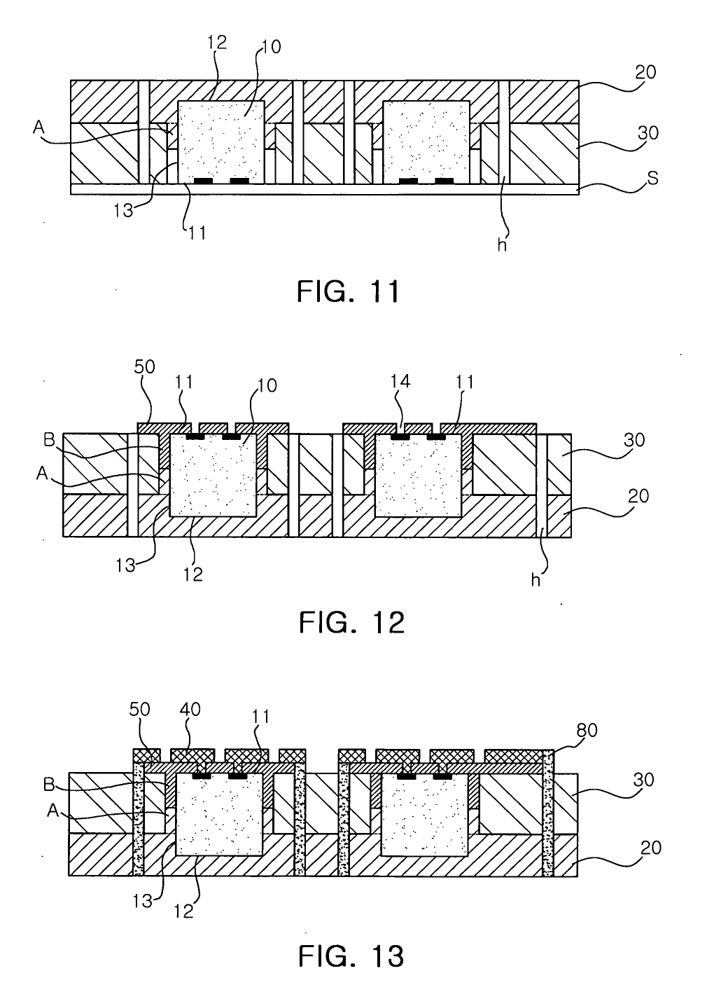

FIGS. 11 through 13 are cross-sectional views for illustrating a method of manufacturing a semiconductor chip package according to another exemplary embodiment of the present invention.

FIGS. 11 through 13 correspond to FIGS. 7 through 9, and different elements from the above-described embodiment will be mainly described, and detailed description of like elements will be omitted.

As shown in FIG. 11, the first lamination layer 20 is formed on the second lamination layer 30 and the second faces 12. Subsequently, via holes h are formed, each of which penetrates the first and second lamination layers 20 and 30. The via holes h may be formed by using a known method such as etching, laser drilling or the like.

The process of forming the via holes h is not specifically limited, and may be performed separately in the processes of laminating the second lamination layer 30 and the first lamination layer 20.

As shown in FIG. 12, the support S is removed to expose the first faces 11 having the chip pads 14, and the insulating layer 50 is formed on the first faces 11 of the semiconductor chips 10 and the second lamination layer 30.

Thereafter, as shown in FIG. 13, redistribution patterns 40 are formed and electrically connected to the chip pads exposed by the insulating layer 50. Here, a via contact 80 is formed in each via hole h by fusing a conductive material so as to be electrically connected to the redistribution pattern 40.

The conductive material may be Al, Cu, Sn, Ni, Au or Ag. The via contact 80 may be formed by the evaporation of a conductive material, electro-plating, electroless-plating or screen-printing, or the like.

Accordingly, a semiconductor chip package including the via contacts as shown in FIG. 3 may be manufactured.

As described above, a multilayer semiconductor chip package including first and second semiconductor chips can be manufactured, due to the via contacts electrically connected to the first and second semiconductor chips and the redistribution patterns of the first and second semiconductor chips.

As set forth above, according to exemplary embodiments of the invention, the active surfaces of the semiconductor chips can be formed at the same level, thereby facilitating the subsequent wafer-level packaging process such as the process of forming redistribution patterns. The lamination process is used in the formation of a wafer form, thereby achieving high price competitiveness, and spot-curing may be used instead of a long-time curing process. Accordingly, chip shift, caused by the variation in a CTE, can be minimized.

While the present invention has been shown and described in connection with the exemplary embodiments, it will be apparent to those skilled in the art that modifications and variations can be made without departing from the spirit and scope of the invention as defined by the appended claims.

What is claimed is:

1. A semiconductor chip package comprising:
a semiconductor chip including a first face having a chip pad, a second face facing the first face, and a side face connecting the first and second faces;
a first lamination layer covering the second face and a portion of the side face;
a second lamination layer disposed on a top surface of the first lamination layer and forming a gap having a predetermined distance from the side face; and
a redistribution pattern disposed on the first face and electrically connected to the chip pad.

2. The semiconductor chip package of claim 1, wherein the first lamination layer includes an extension portion formed in the gap having the predetermined distance.

3. The semiconductor chip package of claim 1, wherein the first lamination layer and the second lamination layer are each formed of polypropylene glycol (PPG) or a liquid crystal polymer (LCP).

4. The semiconductor chip package of claim 1, wherein the first lamination layer and the second lamination layer are formed of the same kind of material.

5. The semiconductor chip package of claim 1, further comprising an insulating layer formed on the first face and the second lamination layer and exposing a portion of the chip pad.

6. The semiconductor chip package of claim 5, wherein the insulating layer includes an extension portion formed in the gap having the predetermined distance.

7. The semiconductor chip package of claim 1, further comprising a via contact electrically connected to the redistribution pattern and penetrating the first and second lamination layers.

8. A method of manufacturing a semiconductor chip package, the method comprising:
forming a through hole in a second lamination layer to which a support is attached;
mounting a semiconductor chip in the through hole such that a first face of the semiconductor chip faces downwards;
forming a first lamination layer on the second lamination layer and the second face;
exposing the first face by removing the support; and
forming a redistribution pattern electrically connected to a chip pad of the first face.

9. The method of claim 8, wherein the second lamination layer has a smaller height than a side face of the semiconductor chip.

10. The method of claim 8, wherein the first lamination layer covers a portion of a side face of the semiconductor chip.

11. The method of claim 8, wherein the through hole has a wider area than the first face of the semiconductor chip so as to form a gap having a predetermined distance between the second lamination layer and a side face of the semiconductor chip.

12. The method of claim 11, wherein the first lamination layer has an extension portion formed in the gap having the predetermined distance.

13. The method of claim 8, further comprising, after the exposing of the first face, forming an insulating layer on the first face of the semiconductor chip and the second lamination layer, the insulating layer exposing a portion of the chip pad of the first face.

14. The method of claim 8, further comprising, after the forming of the first lamination layer, forming a via hole penetrating the first and second lamination layers to form a via contact electrically connected to the redistribution pattern.
